(19) United States
(12) Patent Application Publication
(10) Pub. No.: US 2018/0328551 A1
(43) Pub. Date: Nov. 15, 2018

(54) LED LIGHTING APPARATUS

(71) Applicant: SILICON WORKS CO., LTD., Daejeon (KR)

(72) Inventors: Yong Geun KIM, Suwon-si (KR); Gyeong Sik MUN, Daejeon (KR)

(73) Assignee: SILICON WORKS CO., LTD., Daejeon (KR)

(21) Appl. No.: 15/775,899

(22) PCT Filed: Nov. 15, 2016
(86) PCT No.: PCT/KR2016/013130

§ 371 Date: May 14, 2018

(30) Foreign Application Priority Data
Nov. 17, 2015 (KR) 10-2015-0161093

(51) Int. Cl. F21S 2/00; G01R 27/08; H05B 33/08; H05B 37/02

(52) U.S. Cl. CPC F21S 2/005; G01R 27/08; F21Y 2115/10; H05B 37/02; H05B 33/0809

(57) ABSTRACT

Disclosed is an LED lighting apparatus using a standardized module. The LED lighting apparatus can be configured by assembling a standardized light emitting module and a driving module reflecting a required specification. The driving module includes a driver configured to provide a current path corresponding to light emission of one or more LED groups and regulate a driving current, a sensing resistor connected to the current path of the driver, diodes installed for the respective channel terminals of the driver in order to block a reverse current, and one or more capacitors connected in parallel to the one or more LED groups.

### BACKGROUND

### 1. Technical Field

The present disclosure relates to an LED lighting apparatus, and more particularly, to an LED lighting apparatus using a standardized module.

### 2. Related Art

A lighting apparatus is designed to use a light source which exhibits high light emission efficiency using a small amount of energy, in order to reduce energy consumption. Representative examples of the light source used in the lighting apparatus may include an LED.

The LED is differentiated from other light sources in terms of various aspects such as energy consumption, lifetime, and light quality. Since the LED is driven by a current, the lighting apparatus using the LED as a light source requires many additional circuits for driving a current.

In order to solve the above-described problem, an AC direct-type lighting apparatus has been developed. The AC direct-type lighting apparatus is configured to convert an AC voltage into a rectified voltage, and drive a current using the rectified voltage such that the LED emits light. The rectified voltage indicates a voltage obtained by full-wave rectifying an AC voltage. Since the AC direct-type lighting apparatus directly uses a rectified voltage without using an inductor and capacitor, the AC direct-type lighting apparatus has a satisfactory power factor. The lighting apparatus using an LED is referred to as an LED lighting apparatus.

The LED lighting apparatus is turned off when the level of the rectified voltage is low, and turned on when the level of the rectified voltage is high. The LED lighting apparatus is repeatedly turned on/off according to level changes of the rectified voltage, because the LED lighting apparatus has an AC waveform. That is, as the LED lighting apparatus is repeatedly turned on/off, flicker may occur. The flicker acts as a main factor to reduce the quality of lighting. Therefore, the LED lighting apparatus needs to remove the flicker in order to provide high-quality lighting.

The design of the LED lighting apparatus may be required to be changed according to various specifications, if necessary. For example, when the LED lighting apparatus is designed and manufactured, the above-described flicker reduction function may be required or not.

In general, all components of the LED lighting apparatus need to be designed and manufactured for each required specification.

However, when all of the components are designed and manufactured according to the required specification, a lot of effort, time and cost may be needed to develop and manufacture the LED lighting apparatus.

### SUMMARY

Various embodiments are directed to an LED lighting apparatus capable of reducing flicker which occurs in response to a change of a rectified voltage, thereby providing high-quality lighting.

Also, various embodiments are directed to an LED lighting apparatus which can be configured by assembling modules for implementing a required function into the other modules among a plurality of standardized modules, thereby satisfying a required specification while reducing the effort, time and cost required for developing and manufacturing the LED lighting apparatus.

Also, various embodiments are directed to an LED lighting apparatus which can block a reverse current flow in which a discharge current of a capacitor connected in parallel to an LED group flows through a channel terminal via a driver, in order to reduce flicker.

In an embodiment, an LED lighting apparatus may include: a lighting module including a lighting unit having LEDs divided into a plurality of LED groups which sequentially emit light in response to changes of a rectified voltage; and a driving module including: a driver configured to provide a current path corresponding to light emission of the plurality of LED groups; a capacitor connected in parallel to one or more LED groups among the plurality of LED groups, charged with the rectified voltage, and configured to provide a discharge current for flicker reduction to the one or more LED groups; and a plurality of diodes installed for the respective channel terminals of the driver, and configured to block a reverse current flow in which the discharge current flows through the channel terminals via the driver.

In another embodiment, an LED lighting apparatus may include: a light emitting module including a plurality of LED groups which are connected in series and sequentially turned on/off in response to changes of a rectified voltage, and having a rectified voltage input terminal for receiving the rectified voltage and a plurality of light source module terminals connected to output terminals of the respective LED groups; and a driving module including: a driver having a rectified voltage providing terminal for providing the rectified voltage, driving module terminals corresponding one-to-one to the light source module terminals, and channel terminals connected one-to-one to the driving module terminals, and configured to provide a current path corresponding to light emission of one or more of the LED groups through the channel terminals; a capacitor connected between two terminals selected among the rectified voltage providing terminal and the driving module terminals, connected in parallel to one or more of the LED groups, charged with the rectified voltage, and configured to provide a discharge current for flicker reduction to the one or more LED groups; and a plurality of diodes installed for the respective channel terminals of the driver and configured to block a reverse current flow in which the discharge current flows through the channel terminals via the driver.

### BRIEF DESCRIPTION OF THE DRAWINGS

FIG. 1 is a circuit diagram illustrating an LED lighting apparatus according to an embodiment of the present invention.

FIG. 2 is a detailed circuit diagram of a driver of FIG. 1.

FIGS. 3 and 4 are waveform diagrams for describing an operation of the LED lighting apparatus according to the embodiment of FIG. 1.

FIG. 5 is a circuit diagram illustrating an LED lighting apparatus according to another embodiment of the present invention.

FIG. 6 is a waveform diagram for describing an operation of the LED lighting apparatus according to the embodiment of FIG. 5.

FIG. 7 is a circuit diagram illustrating an LED lighting apparatus according to still another embodiment of the present invention.

FIG. 8 is a waveform diagram for describing an operation of the LED lighting apparatus according to the embodiment of FIG. 7.

### DETAILED DESCRIPTION

Hereafter, embodiments of the present invention will be described in detail with reference to the accompanying drawings. The terms used in the present specification and claims are not limited to typical dictionary definitions, but must be interpreted as meanings and concepts which coincide with the technical idea of the present invention.

Embodiments described in the present specification and configurations illustrated in the drawings are preferred embodiments of the present invention, and do not represent the entire technical idea of the present invention. Thus, various equivalents and modifications capable of replacing the embodiments and configurations may be provided at the point of time that the present application is filed.

An LED lighting apparatus according to an embodiment of the present invention may use a light source having a semiconductor light emitting characteristic to convert electrical energy into light energy, and the light source having a semiconductor light emitting characteristic may include an LED.

The LED lighting apparatus according to the embodiment of the present invention may be implemented in an AC direct type. The AC-direct type lighting apparatus controls an LED to emit light using a rectified voltage obtained by converting an AC voltage. The rectified voltage has a waveform obtained by full-wave rectifying an AC voltage having a sine wave as described above. That is, the rectified voltage has a ripple in which its voltage level rises/falls by the half cycle of a common AC voltage. A current provided to the LED in response to the rectified voltage obtained by converting the AC voltage is referred to as a rectified current.

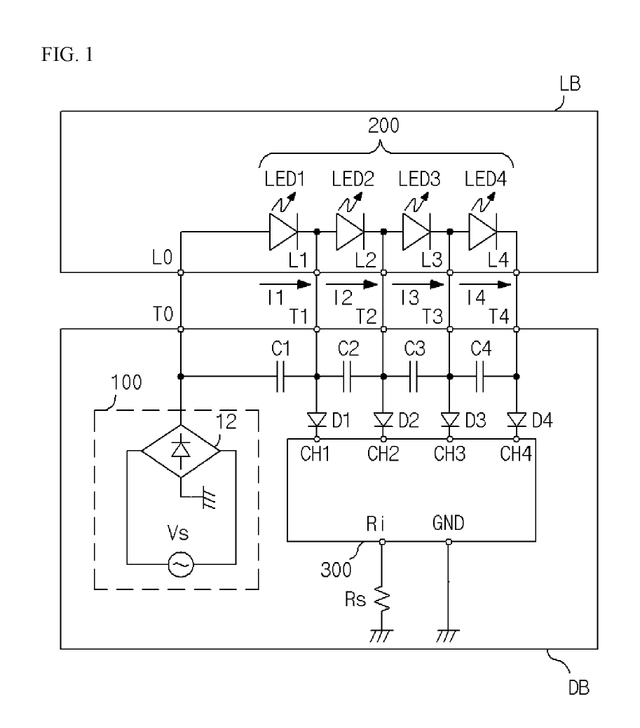

In the present embodiment as illustrated in FIG. 1, a lighting unit 200 including LEDs is configured to emit light using an AC power supply Vs, and a driver 300 is configured to provide a current path in response to the light emission of the lighting unit 200.

Referring to FIG. 1, the lighting apparatus according to the present embodiment includes a power supply unit 100, the lighting unit 200, a driver 300 and a sensing resistor Rs.

The lighting unit 200 may be included in a light source module LB constituted by one substrate, and the LEDs of the lighting unit 200 may be mounted on the substrate constituting the light source module LB. The light source module LB may be provided as a standardized module. More specifically, the light source module LB may include a rectified voltage input terminal L0 and a plurality of light source module terminals L1 to L4.

Furthermore, a driving module DB constituted by another substrate includes the power supply unit 100, the driver 300, the sensing resistor Rs, capacitors C1 to C4 and diodes D1 to D4. The driving module DB may include a rectified voltage providing terminal T0 and a plurality of driving module terminals T1 to T4.

The light source module LB and the driving module DB have standardized terminals corresponding to each other, and are electrically connected to each other through connections between the terminals. More specifically, the rectified voltage providing terminal T0 is connected to the rectified voltage input terminal L0 of the light source module LB, and the plurality of driving module terminals T1 to T4 are connected to the respective light source module terminals L1 to L4 of the light source module LB. The connections between the terminals may indicate electrical connections between electrical connection members between the power supply unit 100 and the lighting unit 200 and output terminals of LED groups LED1 to LED4 of the lighting unit 200 and channel terminals CH1 to CH4 of the driver 300. The connections may be implemented through a connector or the like.

FIG. 1 illustrates one embodiment constituted by a plurality of modules, and the present invention may be embodied in various manners by a manufacturer. The driving module DB of FIG. 1 may include the capacitors C1 to C4. The driving module DB may be coupled to the light source module LB in order to provide a flicker reduction function, and parts mounted on the driving module DB may be modified in various manners by a manufacturer.

The power supply unit 100 full-wave rectifies an AC voltage of the AC power supply Vs, and outputs the rectified voltage Vrec. The power supply unit 100 may include the AC power supply Vs for providing the AC voltage and a rectifier circuit 12 for full-wave rectifying the AC voltage and outputting the rectified voltage Vrec. The AC power supply Vs may include a commercial power supply.

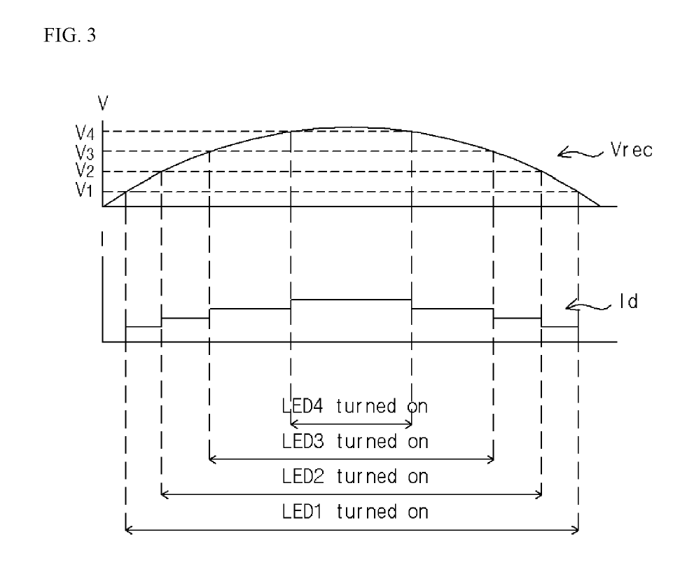

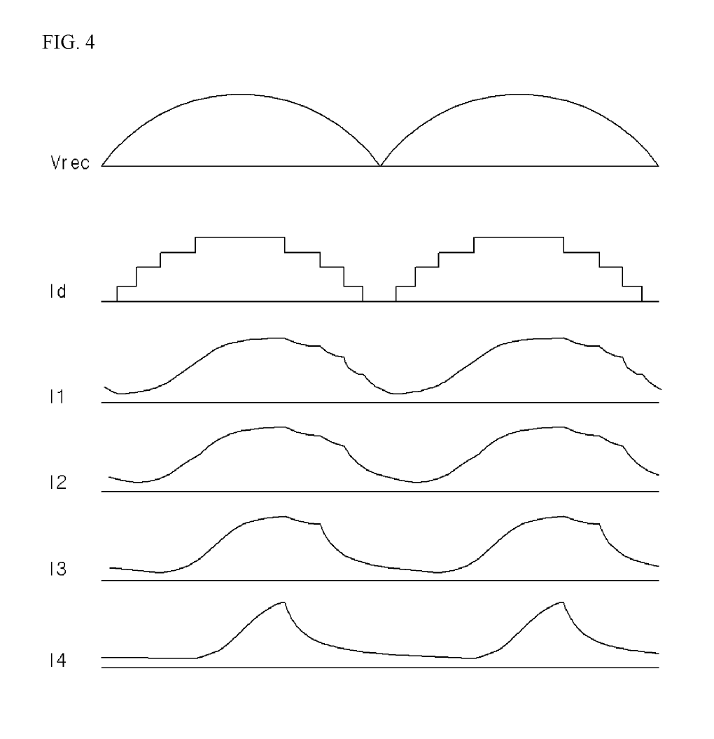

In the present embodiment, a rise or fall of the rectified voltage Vrec may be understood as a rise or fall in ripple of the rectified voltage Vrec. In response to a rise or fall of the rectified voltage Vrec, the amount of driving current Id (refer to FIGS. 3 and 4) inputted to the lighting unit 200 from the rectifier circuit 12 is changed.

The power supply unit 100 of the driving module DB is configured to provide the rectified voltage Vrec to the lighting unit 200 through the rectified voltage providing terminal T0 and the rectified voltage input terminal L0 of the light source module LB.

The lighting unit 200 may include LEDs which are divided into one or more LED groups. The lighting unit 200 sequentially turns on/off the LED groups in response to increases/decreases of the rectified voltage Vrec provided from the power supply unit 100.

FIG. 1 illustrates that the lighting unit 200 includes four LED groups LED1 to LED4. Each of the LED groups LED1 to LED4 may include one or more LEDs. For convenience of description, each of the LED groups is represented by one symbol.

The four LED groups LED1 to LED4 of the lighting unit 200 included in the light source module LB are connected in series, the rectified voltage input terminal L0 is connected to the input terminal of the LED group LED1, and the light source module terminals L1 to L4 are connected in parallel to the output terminals of the respective LED groups LED1 to LED4.

The driver 300 compares a current sensing voltage to reference voltages corresponding to the respective LED groups LED1 to LED4, provides a current path for the LED groups LED1 to LED4, and performs current regulation on the driving current Id flowing through the current path. The current sensing voltage and the reference voltages will be described later.

The driver 300 has channel terminals CH1 to CH4 connected to the output terminals of the respective LED groups LED1 to LED4, a ground terminal GND for connection with the ground, and a current sensing terminal Ri connected to the sensing resistor Rs. The driver 300 changes current paths between the channel terminals CH1 to CH4 and the current sensing terminal Ri, and regulates the driving current Id flowing through the sensing resistor Rs connected to the current sensing terminal Ri.

In particular, the channel terminals CH1 to CH4 of the driver 300 are connected to the output terminals of the LED groups LED1 to LED4 through the driving module terminals T1 to T4 and the light source module terminals L1 to L4, respectively.

The sensing resistor Rs is connected between the current sensing terminal Ri of the driver 300 and the ground, and provides current sensing voltages corresponding to the light emitting states of the LED groups LED1 to LED4. The driving current Id flowing through the sensing resistor Rs may be changed depending on the light emitting states of the LED groups LED1 to LED4 of the lighting unit 200.

When the rectified voltage Vrec rises to sequentially reach the light emission voltages of the respective LED groups LED1 to LED4, the driver 300 provides current paths corresponding to light emissions of the LED groups LED1 to LED4.

The light emission voltage V4 for controlling the LED group LED4 to emit light is defined as a voltage for controlling all of the LED groups LED1 to LED4 to emit light. The light emission voltage V3 for controlling the LED group LED3 to emit light is defined as a voltage for controlling all of the LED groups LED1 to LED3 to emit light. The light emission voltage V2 for controlling the LED group LED2 to emit light is defined as a voltage for controlling both of the LED groups LED1 and LED2 to emit light. The light emission voltage V1 for controlling the LED group LED1 to emit light is defined as a voltage for controlling only the LED group LED1 to emit light.

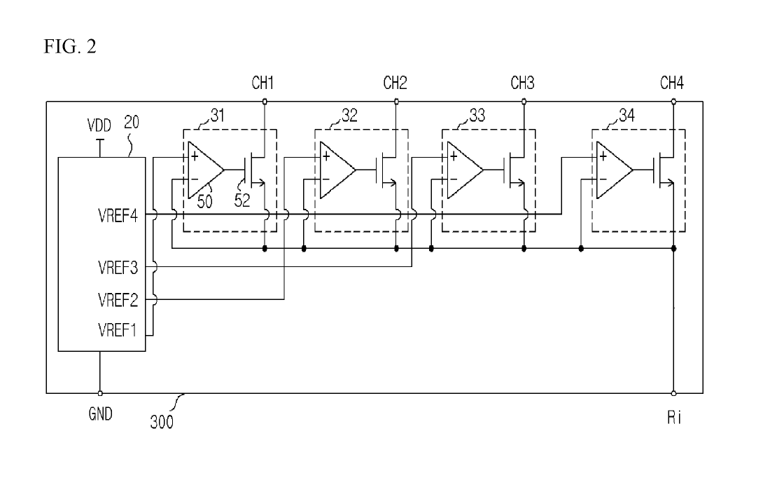

As illustrated in FIG. 2, the driver 300 includes switching circuits 31 to 34 for providing a current path for the LED groups LED1 to LED4 and a reference voltage supply unit 20 for supplying the reference voltages VREF1 to VREF4.

The reference voltage supply unit 20 may be configured to provide the reference voltages VREF1 to VREF4 having different levels, depending on a designer's intention.

In another embodiment, the reference voltage supply unit 20 may include independent voltage supply sources for providing the reference voltages VREF1 to VREF4 having different levels, respectively. The reference voltage supply unit 20 may include a plurality of resistors connected in series to receive a constant voltage VDD, and output the reference voltage VREF1 to VREF4 having different levels to nodes between the respective resistors. At this time, the independent voltage supply sources may correspond to the respective resistors connected in series. One terminal of the reference voltage supply unit 20 is connected to the ground terminal GND in order to share the ground with the sensing resistor Rs.

Among the reference voltages VREF1 to VREF4 having different levels, the reference voltage VREF1 may have the lowest voltage level, and the reference voltage VREF4 may have the highest voltage. The voltage levels of the reference voltages VREF1 to VREF4 may have a relation of VREF1>VREF2>VREF3>VREF4.

The reference voltage VREF1 has a level for turning off the switching circuit 31 at a point of time that the LED group LED2 emits light. More specifically, the reference voltage VREF1 may be set to a lower level than the current sensing voltage formed in response to the light emission of the LED group LED2.

The reference voltage VREF2 has a level for turning off the switching circuit 32 at a point of time that the LED group LED3 emits light. More specifically, the reference voltage VREF2 may be set to a lower level than the current sensing voltage formed in response to the light emission of the LED group LED3.

The reference voltage VREF3 has a level for turning off the switching circuit 33 at a point of time that the LED group LED4 emits light. More specifically, the reference voltage VREF3 may be set to a lower level than the current sensing voltage formed in response to the light emission of the LED group LED4.

The reference voltage VREF4 may be set to a higher level than the current sensing voltage in the upper limit level region of the rectified voltage.

The switching circuits 31 to 34 are connected to the sensing resistor Rs in common through the current sensing terminal Ri, in order to perform current regulation and to form a current path.

The switching circuits 31 to 34 compare the current sensing voltage of the sensing resistor Rs to the reference voltages VREF1 to VREF4 of the reference voltage supply unit 20, and form a current path corresponding to light emission of the lighting unit 200.

Each of the switching circuits 31 to 34 receives a high-level reference voltage as the switching circuit is connected to an LED group remote from the position to which the rectified voltage is applied.

Each of the switching circuits 31 to 34 may include a comparator 50 and a switching element, and the switching element may be implemented with an NMOS transistor 52.

Each of the comparators 50 of the switching circuits 31 to 34 has a positive input terminal (+) configured to receive a reference voltage, a negative input terminal (−) configured to receive a current sensing voltage, and an output terminal configured to output a comparison result between the reference voltage and the current sensing voltage.

The NMOS transistors 52 of the respective switching circuits 31 to 34 perform a switching operation for controlling a flow of the driving current Id according to outputs of the comparators, applied to the gates thereof.

In the present embodiment, the driving module DB includes the capacitors, and the capacitors are connected between two terminals selected among the voltage providing terminal T0 and the driving module terminals T1 to T4, connected in parallel to one or more of the LED groups LED1 to LED4, charged with the rectified voltage Vrec, and provide a discharge current for flicker reduction to one or more LED groups.

FIG. 1 illustrates an embodiment in which the capacitors C1 to C4 are connected in parallel to the respective LED groups LED1 to LED4. That is, the capacitor C1 is installed between the rectified voltage providing terminal T0 and the driving module terminal T1 so as to be connected in parallel to the LED group LED1, the capacitor C2 is installed between the driving module terminals T1 and T2 so as to be connected in parallel to the LED group LED2, the capacitor C3 is installed between the driving module terminals T2 and T3 so as to be connected in parallel to the LED group LED3, and the capacitor C4 is installed between the driving module terminals T3 and T4 so as to be connected in parallel to the LED group LED4.

While the rectified voltage Vrec rises, the capacitors C1 to C4 start to be charged when the LED groups LED1 to LED4 connected in parallel to the capacitors C1 to C4 emit light. Furthermore, while the rectified voltage Vrec falls, the discharges of the capacitors C1 to C4 start to be discharged before the LED groups LED1 to LED4 connected in parallel to the capacitors C1 to C4 are turned off. At this time, charge/discharge times may be decided according to the capacitances of the respective capacitors C1 to C4.

In the present embodiment, the driving module DB includes diodes D1 to D4, and the diodes D1 to D4 are installed at the respective channel terminals CH1 to CH4 of the driver 300, and block a reverse current flow in which a discharge current flows through each of the channel terminals CH1 to CH4 via the driver 300. The configuration for blocking the reverse current flow of the discharge current by the diodes D1 to D4 will be described in detail later.

First, an operation of an embodiment based on the supposition that the capacitors C1 to C4 are not installed in the configuration of FIGS. 1 and 2 will be described with reference to FIG. 3.

When the rectified voltage Vrec is in the initial state, all of the switching circuits 31 to 34 maintain an on-state, because the reference voltages VREF1 to VREF4 applied to the positive input terminals (+) thereof are higher than the current sensing voltage applied to the negative input terminals (−) thereof. At this time, the LED groups LED1 to LED4 are maintained in an off-state.

Then, when the rectified voltage Vrec rises to reach the light emission voltage V1, the LED group LED1 emits light. When the LED group LED1 emits light, the switching circuit 31 connected to the LED group LED1 provides a current path. That is, the current path is formed by the switching circuit 31.

When the LED group LED1 emits light, the driving current Id starts to flow through the current path formed by the switching circuit 31. However, since the level of the current sensing voltage at this time is low, the on-states of the switching circuits 31 to 34 are not changed.

Then, while the rectified voltage Vrec reaches the light emission voltage V2, the driving current Id is regulated to a constant amount through a regulation operation of the switching circuit 31.

Then, when the rectified voltage Vrec reaches the light emission voltage V2, the LED group LED2 emits light. When the LED group LED2 emits light, the switching circuit 32 connected to the LED group LED2 provides a current path. At this time, the LED group LED1 also maintains the light emitting state.

When the LED group LED2 emits light, the driving current Id starts to flow through the current path formed by the switching circuit 32. At this time, the level of the current sensing voltage is higher than the reference voltage VREF1. Thus, the NMOS transistor 52 of the switching circuit 31 is turned off by an output of the comparator 50. That is, the switching circuit 31 is turned off, and the switching circuit 32 provides a selective current path corresponding to the light emission of the LED group LED2.

Then, while the rectified voltage Vrec reaches the light emission voltage V3, the driving current Id is regulated to a constant amount through a regulation operation of the switching circuit 32.

When the rectified voltage Vrec reaches the light emission voltage V3, the LED group LED3 emits light. When the LED group LED3 emits light, the switching circuit 33 connected to the LED group LED3 provides a current path. At this time, the LED groups LED1 and LED2 also maintain the light emitting state.

When the LED group LED3 emits light, the driving current Id starts to flow through the current path formed by the switching circuit 33. At this time, the level of the current sensing voltage is higher than the reference voltage VREF2. Thus, the NMOS transistor 52 of the switching circuit 32 is turned off by an output of the comparator 50. That is, the switching circuit 32 is turned off, and the switching circuit 33 provides a selective current path corresponding to the light emission of the LED group LED3.

Then, while the rectified voltage Vrec reaches the light emission voltage V4, the driving current Id is regulated to a constant amount through a regulation operation of the switching circuit 33.

When the rectified voltage Vrec reaches the light emission voltage V4, the LED group LED4 emits light. When the LED group LED4 emits light, the switching circuit 34 connected to the LED group LED4 provides a current path. At this time, the LED groups LED1 to LED3 also maintain the light emitting state.

When the LED group LED4 emits light, the driving current Id starts to flow through the current path formed by the switching circuit 34. At this time, the level of the current sensing voltage is higher than the reference voltage VREF3. Thus, the NMOS transistor 52 of the switching circuit 33 is turned off by an output of the comparator 50. That is, the switching circuit 33 is turned off, and the switching circuit 34 provides a selective current path corresponding to the light emission of the LED group LED4.

Then, the rectified voltage Vrec starts to fall after reaching the upper limit level.

While the rectified voltage Vrec reaches the upper limit level, the driving current Id is regulated to a constant amount through a regulation operation of the switching circuit 34.

On the contrary, when the rectified voltage Vrec falls in a stepwise manner to the light emission voltages V4 to V1 from the upper limit level, the LED groups LED4 to LED1 are sequentially turned off. The driving current Id also decreases in a stepwise manner in response to the turn-off of the LED groups LED4 to LED1.

As described above, the driver 300 changes the current path in response to the changes in light emitting state of the LED groups LED1 to LED4, and regulates the driving current Id on the current path.

When the capacitors C1 to C4 are not installed in the embodiment of FIG. 1, each of the LED groups LED1 to LED4 is turned off in a section where the level of the rectified voltage Vrec is low, because the driving current Id required for light emission is not sufficient. That is, the waveform diagram of FIG. 3 illustrates the phenomenon that the lighting apparatus flickers while all of the LED groups are turned off by the rectified voltage Vrec of which the level is periodically changed.

The LED lighting apparatus according to the embodiment of FIG. 1 can reduce flicker through the operation of the capacitors C1 to C4. Hereafter, the configuration for reducing flicker through the capacitors C1 to C4 in the embodiment of FIG. 1 will be described. Since the configuration in which the driver 300 provides the current paths for the light emissions of the LED groups LED1 to LED4 corresponding to the changes of the rectified voltage Vrec and performs current regulation on each of the current paths can be understood through the above-described operation, the duplicated descriptions are omitted herein.

In the embodiment of FIG. 1, the capacitors C1 to C4 are connected in parallel to the respective LED groups LED1 to LED4 as described above. The LED lighting apparatus according to the embodiment of FIG. 1 includes the diodes D1 to D4 which are installed at the respective channel terminals CH1 to CH4 of the driver 300, and block a reverse current flow in which a discharge current flows through the channel terminals CH1 to CH4 via the driver 300.

In FIG. 1, the driving current Id is divided into driving currents I1 to I4 corresponding to light emissions of the respective LED groups LED1 to LED4.

The driving current I4 flows through the LED group LED4. The driving current I4 may be set to the sum of the current provided by the rectifier circuit 12 of the power supply unit 100 or the driving current Id and a discharge current from the capacitor C4.

The capacitor C4 starts to be charged with the current provided by the rectifier circuit 12 from the point of time that the rectified voltage Vrec rises over the light emission voltage V4. While the rectified voltage Vrec is retained at the light emission voltage V4 or more, the charging operation by the current provided from the rectifier circuit 12 is maintained. Then, when the rectified voltage Vrec falls below the light emission voltage V4, the capacitor C4 provides a discharge current caused by the charge voltage to the LED group LED4.

The discharge current of the capacitor C4 is provided to the LED group LED4, and the LED group LED4 maintains light emission using the discharge current, with the rectified voltage Vrec retained at the light emission voltage V4 or less.

The diode D4 blocks a reverse current flow which may occur when the potential of the output terminal of the LED group LED4 becomes lower than the potential of the channel terminal CH4 of the driver 300.

Furthermore, the diode D4 blocks a current path which is formed through the diode D3, the channel terminal CH3, the NMOS transistor of the turned-on switching circuit 33 and the NMOS transistor of the turned-on switching circuit 34 in the driver 300, and the channel terminal CH4, and induces the reverse current flow of the discharge current of the capacitor C4. That is, the diode D4 can block the reverse current flow between the channel terminal CH4 of the driver 300 and the capacitor C4, thereby preventing a discharge current leakage.

The diodes D1, D2 and D3 can prevent a discharge current leakage by blocking a current flowing to the LED groups LED1, LED2 and LED3 through the diode D3 and the driver 300.

While the rectified voltage Vrec is retained at the light emission voltage V4 or more, the driving current I4 has a waveform decided by the current provided from the rectifier circuit 12. Then, when the rectified voltage Vrec falls below the light emission voltage V4, the driving current I4 has a waveform depending on the discharge current of the capacitor C4.

The driving current I3 flows through the LED group LED3. The driving current I3 may be set to the sum of the current provided from the rectifier circuit 12 of the power supply unit 100 or the driving current Id and a discharge current from the capacitor C3.

The capacitor C3 starts to be charged with the current provided by the rectifier circuit 12 from the point of time that the rectified voltage Vrec rises over the light emission voltage V3. While the rectified voltage Vrec is retained at the light emission voltage V3 or more, the charging operation by the current provided from the rectifier circuit 12 is maintained. Then, when the rectified voltage Vrec falls below the light emission voltage V3, the capacitor C3 provides a discharge current caused by the charge voltage to the LED group LED3.

The discharge current of the capacitor C3 is provided to the LED group LED3, and the LED group LED3 maintains light emission using the discharge current, with the rectified voltage Vrec retained at the light emission voltage V3 or less.

The diode D3 blocks a reverse current flow which may occur when the potential of the output terminal of the LED group LED3 becomes lower than the potential of the channel terminal CH3 of the driver 300.

Furthermore, the diode D3 blocks a current path which is formed through the diode D2, the channel terminal CH2, the NMOS transistor of the turned-on switching circuit 32 and the NMOS transistor of the turned-on switching circuit 33 in the driver 300, and the channel terminal CH3, and induces the reverse current flow of the discharge current of the capacitor C3. That is, the diode D3 can block the reverse current flow between the channel terminal CH3 of the driver 300 and the capacitor C3, thereby preventing a discharge current leakage.

The diodes D1, D2 and D4 can prevent a discharge current leakage by blocking a current flowing to the LED groups LED1, LED2 and LED4 through the diode D2 and the driver 300.

The driving current I3 has a waveform that is increased by the current provided from the rectifier circuit 12 from the point of time that the rectified voltage Vrec rises over the light emission voltage V3 to a point of time that the rectified voltage Vref falls to the light emission voltage V4 after reaching the highest value.

When the rectified voltage Vref falls from the light emission voltage V4 to the light emission voltage V3, the driving current I3 is affected by the discharge of the capacitor C3, which corresponds to a surplus voltage equal to a difference between the rectified voltage Vrec and the light emission voltage V3. When the rectified voltage Vref falls below the light emission voltage V3, the driving current I3 is affected by the discharge current of the capacitor C3. That is, the curve of the driving current I3 in the section where the rectified voltage Vrec falls from the light emission voltage V4 to the light emission voltage V3 is decided by the discharge of the capacitor C3, corresponding to the surplus voltage, and the curve of the driving current I3 in the section where the rectified voltage Vrec falls below the light emission voltage V3 is decided by the discharge current of the capacitor C3.

The driving current I2 flows through the LED group LED2. The driving current I2 may be set to the sum of the current provided by the rectifier circuit 12 of the power supply unit 100 or the driving current Id and a discharge current from the capacitor C2.

The capacitor C2 starts to be charged with the current provided by the rectifier circuit 12 from the point of time that the rectified voltage Vrec rises over the light emission voltage V2. While the rectified voltage Vrec is retained at the light emission voltage V2 or more, the charging operation by the current provided from the rectifier circuit 12 is maintained. Then, when the rectified voltage Vrec falls below the light emission voltage V2, the capacitor C2 provides a discharge current caused by the charge voltage to the LED group LED2.

The discharge current of the capacitor C2 is provided to the LED group LED2, and the LED group LED2 maintains light emission using the discharge current, with the rectified voltage Vrec retained at the light emission voltage V2 or less.

The diode D2 blocks a reverse current flow which may occur when the potential of the output terminal of the LED group LED2 becomes lower than the potential of the channel terminal CH2 of the driver 300.

The driving current I2 has a waveform that is increased by the current provided from the rectifier circuit 12 from the point of time that the rectified voltage Vrec rises over the light emission voltage V2 to the point of time that the rectified voltage Vref falls to the light emission voltage V4 after reaching the highest value.

Furthermore, the diode D2 blocks a current path which is formed through the diode D1, the channel terminal CH1, the NMOS transistor of the turned-on switching circuit 31 and the NMOS transistor of the turned-on switching circuit 32 in the driver 300, and the channel terminal CH2, and induces the reverse current flow of the discharge current of the capacitor C2. That is, the diode D2 can block the reverse current flow between the channel terminal CH2 of the driver 300 and the capacitor C2, thereby preventing a discharge current leakage.

The diodes D1, D3 and D4 may prevent a discharge current leakage by blocking a current flowing to the LED groups LED1, LED3 and LED4 through the diode D1 and the driver 300.

The driving current I2 follows the change of the driving current I3 when the rectified voltage Vrec falls between the light emission voltages V4 and V3. Furthermore, when the rectified voltage Vref falls between the light emission voltages V3 and V2, the driving current I2 is affected by the discharge of the capacitor C2, which corresponds to a surplus voltage equal to a difference between the rectified voltage Vrec and the light emission voltage V2. When the rectified voltage Vref falls below the light emission voltage V2, the driving current I2 is affected by the discharge of the capacitor C2. That is, the curve of the driving current I2 in the section where the rectified voltage Vrec falls from the light emission voltage V3 to the light emission voltage V2 is decided by the discharge of the capacitor C2, corresponding to the surplus voltage, and the curve of the driving current I2 in the section where the rectified voltage Vrec falls below the light emission voltage V2 is decided by the discharge current of the capacitor C2.

The driving current I1 flows through the LED group LED1. The driving current I1 may be set to the sum of the current provided by the rectifier circuit 12 of the power supply unit 100 or the driving current Id and a discharge current from the capacitor C1.

The capacitor C1 starts to be charged with the current provided by the rectifier circuit 12 from the point of time that the rectified voltage Vrec rises over the light emission voltage V1. While the rectified voltage Vrec is retained at the light emission voltage V1 or more, the charging operation by the current provided from the rectifier circuit 12 is maintained. Then, when the rectified voltage Vrec falls below the light emission voltage V1, the capacitor C1 provides a discharge current caused by the charge voltage to the LED group LED1.

The discharge current of the capacitor C1 is provided to the LED group LED1, and the LED group LED1 maintains light emission using the discharge current, with the rectified voltage Vrec retained at the light emission voltage V1 or less.

The diode D1 blocks a reverse current flow which may occur when the potential of the output terminal of the LED group LED1 becomes lower than the potential of the channel terminal CH1 of the driver 300.

The diode D1 blocks a current path which induces a reverse current flow of the discharge current of the capacitor C1, which is formed through the sensing resistor Rs, the NMOS transistor of the turned-on switching circuit 31 in the driver 30, and the channel terminal CH1. That is, the diode D1 can block the reverse current flow between the channel terminal CH1 of the driver 300 and the capacitor C1, thereby preventing a discharge current leakage.

The diodes D2, D3 and D4 can prevent a discharge current leakage by blocking a current flowing to the LED groups LED2, LED3 and LED4 through the sensing resistor Rs and the driver 300.

The driving current I1 has a waveform that is increased by the current provided from the rectifier circuit 12 from the point of time that the rectified voltage Vrec rises over the light emission voltage V1 to the point of time that the rectified voltage Vref falls to the light emission voltage V4 after reaching the highest value.

The driving current I1 follows the change of the driving current I1 when the rectified voltage Vrec falls between the light emission voltages V4 and V2. Furthermore, when the rectified voltage Vref falls between the light emission voltages V2 and V1, the driving current I1 is affected by the discharge of the capacitor C1, which corresponds to a surplus voltage equal to a difference between the rectified voltage Vrec and the light emission voltage V1. When the rectified voltage Vref falls below the light emission voltage V1, the driving current I1 is affected by the discharge of the capacitor C1. That is, the curve of the driving current I1 in the section where the rectified voltage Vrec falls from the light emission voltage V2 to the light emission voltage V1 is decided by the discharge of the capacitor C1, corresponding to the surplus voltage, and the curve of the driving current I1 in the section where the rectified voltage Vrec falls below the light emission voltage V1 is decided by the discharge current of the capacitor C1.

As described above, the LED lighting apparatus according to the present embodiment can provide the discharge currents caused by the capacitors C1 to C4 when the rectified voltage Vrec falls, and maintain light emission using the discharge currents even in a section where the rectified voltage Vrec is low.

The amounts of discharge currents may be decided according to the capacitances of the capacitors C1 to C4, and the capacitances of the capacitors C1 to C4 may be set to such an extent that the driving current I1 can be retained at a level at which the LED group LED1 can emit light at all times.

In the above-described configuration, the LED lighting apparatus can reduce flicker while emitting light.

In the present embodiment, the LED lighting apparatus is configured to secure the driving current I1 at which the LED group LED1 can emit light at all times. Depending on a designer's selection, however, the capacitances of the capacitors may be changed to secure a driving current at which two or more LED groups can maintain light emission.

In order to reduce flicker, the capacitors may be configured in various manners.

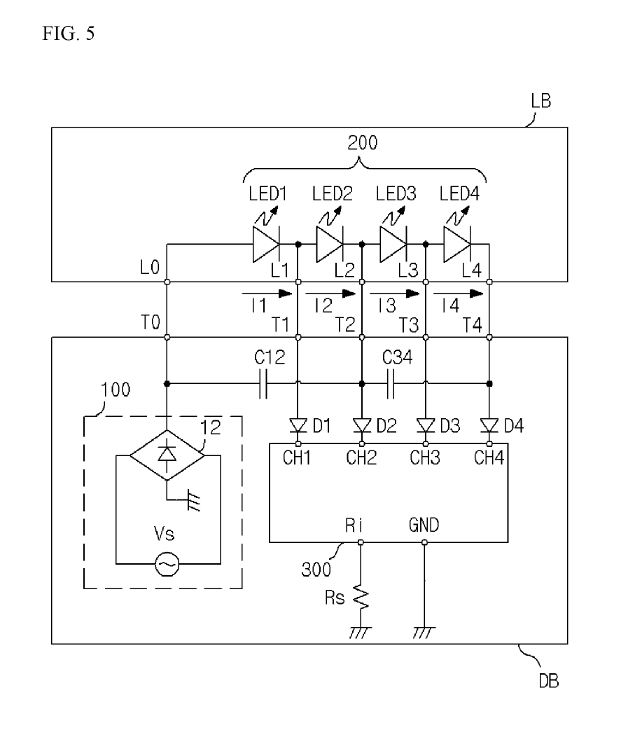

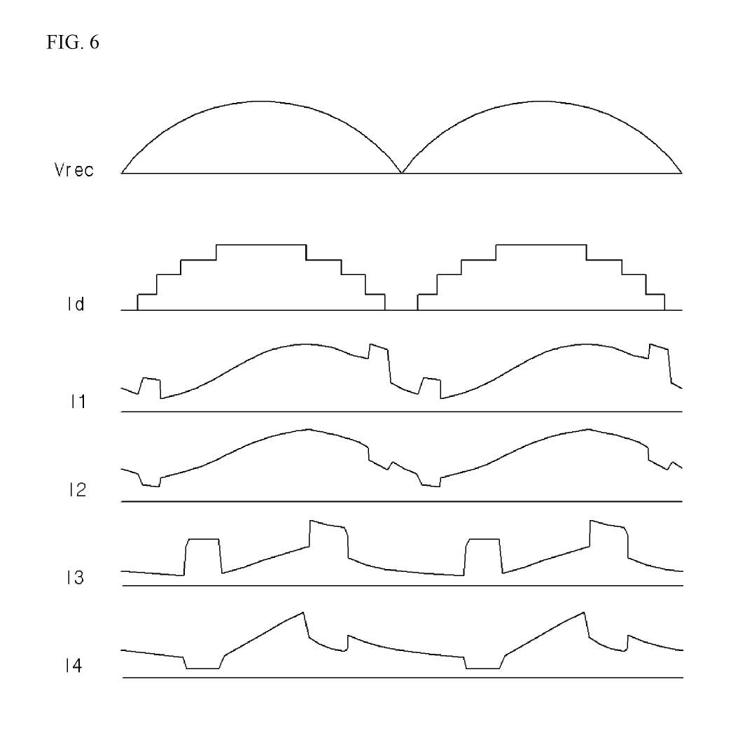

For example, the present invention may be embodied into a configuration in which the LED lighting apparatus includes a capacitor C12 connected in parallel to the LED groups LED1 and LED2 and a capacitor C34 connected in parallel to the LED groups LED3 and LED4 as illustrated in FIG. 5. FIG. 5 illustrates that each capacitor is installed for a plurality of LEDs, unlike the configuration in which the capacitors are installed in parallel to the respective LED groups as illustrated in FIG. 1. FIG. 6 illustrates the waveforms of the driving currents Id and I1 to I4 according to the embodiment of FIG. 5.

According to the above-described configuration, the capacitor C12 starts to be charged from the point of time that the rectified voltage Vrec rises over the light emission voltage V2 in the section where the rectified voltage Vrec rises, and the charging is maintained until the rectified voltage Vrec falls to the light emission voltage V4 after rising to the highest value. Furthermore, the capacitor C34 starts to be charged from the point of time that the rectified voltage Vrec rises over the light emission voltage V4 in the section where the rectified voltage Vrec rises, and the charging is maintained until the rectified voltage Vrec falls to the light emission voltage V4 after rising to the highest value. When the rectified voltage Vrec falls below the light emission voltage V2, the capacitor C12 is discharged until the rectified voltage Vrec reaches the light emission voltage V2 again. Furthermore, when the rectified voltage Vrec falls below the light emission voltage V4, the capacitor C34 is discharged until the rectified voltage Vrec reaches the light emission voltage V4 again.

When the rectified voltage Vrec rises from the light emission voltage V1 to the light emission voltage V2 or falls from the light emission voltage V2 to the light emission voltage V1, the driving current I1 increases in response to a current provided from the rectifier circuit 12 through a current path formed through the LED group LED1 and the channel terminal CH1.

When the rectified voltage Vrec rises from the light emission voltage V1 to the light emission voltage V2 or falls from the light emission voltage V2 to the light emission voltage V1, the driving current I2 decreases while the driving current I1 increases, because the discharge of the capacitor C12 is limited by a potential rise of the LED group LED1.

When the rectified voltage Vrec falls from the light emission voltage V4 to the light emission voltage V2, the driving currents I1 and I2 have a waveform corresponding to the sum of the current provided from the rectifier circuit 12 and a discharge current of the capacitor C12.

The driving currents I3 and I4 are changed in the same manner as the relation between the driving currents I1 and I2.

Specifically, when the rectified voltage Vrec rises from the light emission voltage V3 to the light emission voltage V4 or falls from the light emission voltage V4 to the light emission voltage V3, the driving current I3 increases and decreases in response to a current provided from the rectifier circuit 12 through a current path formed through the LED group LED3 and the channel terminal CH3.

When the rectified voltage Vrec rises from the light emission voltage V3 to the light emission voltage V4 or falls from the light emission voltage V4 to the light emission voltage V3, the driving current I4 decreases while the driving current I3 increases, because the discharge of the capacitor C34 is limited by a potential rise of the LED group LED3.

As described above, the LED lighting apparatus according to the present embodiment can provide the discharge currents caused by the capacitors C12 and C34 when the rectified voltage Vrec falls, and maintain light emission by the discharge currents even in a section where the rectified voltage Vrec is low.

In the embodiment of FIG. 5, the amounts of discharge currents may be decided according to the capacitances of the capacitors C12 and C34, and the capacitances of the capacitors C12 and C34 may be set to such an extent that the driving current I1 can be retained at a level at which the LED group LED1 can emit light at all times.

Therefore, the LED lighting apparatus according to the embodiment of FIG. 5 can also reduce flicker while emitting light as in the embodiment of FIG. 1.

In the present embodiment, an operation for preventing a discharge current leakage of the capacitors C12 and C34 may be performed by the diodes D1 to D4.

When the capacitor C34 is discharged, the diode D4 blocks a current path which is formed through the diode D2, the channel terminal CH2, the NMOS transistor of the turned-on switching circuit 32 and the NMOS transistor of the turned-on switching circuit 34 in the driver 300, and the channel terminal CH4, and induces a reverse flow of the discharge current of the capacitor C34. That is, the diode D4 can block the reverse current flow between the channel terminal CH4 of the driver 300 and the capacitor C34, thereby preventing a discharge current leakage.

The diodes D1, D2 and D3 can prevent a discharge current leakage by blocking the discharge current of the capacitor C34 from flowing to the LED groups LED1, LED2 and LED4 through the driver 300.

When the capacitor C12 is discharged, the diode D2 blocks a current path which is formed through the sensing resistor Rs, the NMOS transistor of the turned-on switching circuit 32 in the driver 30, and the channel terminal CH2 and induces a reverse flow of the discharge current of the capacitor C12. That is, the diode D2 can block the reverse current flow between the channel terminal CH2 of the driver 300 and the capacitor C12, thereby preventing a discharge current leakage.

The diodes D1, D3 and D4 can prevent a discharge current leakage by blocking a current flowing to the LED groups LED2, LED3 and LED4 through the sensing resistor Rs and the driver 300.

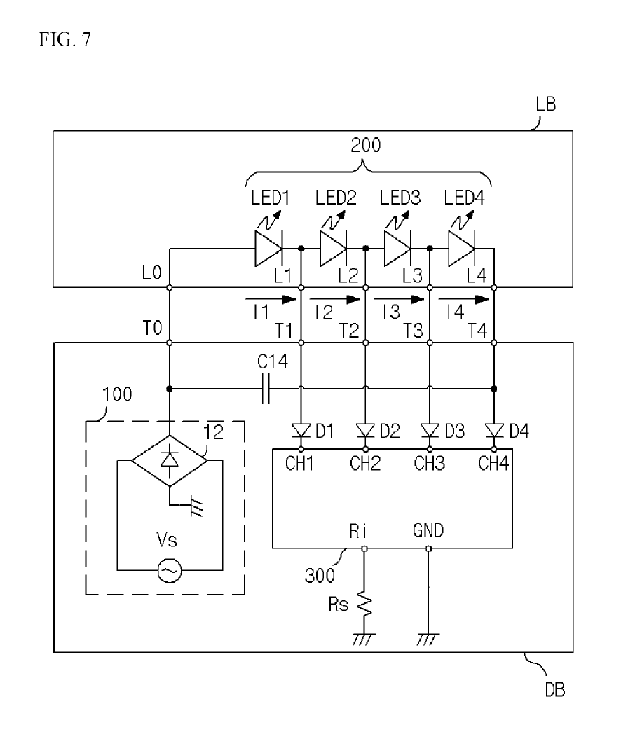

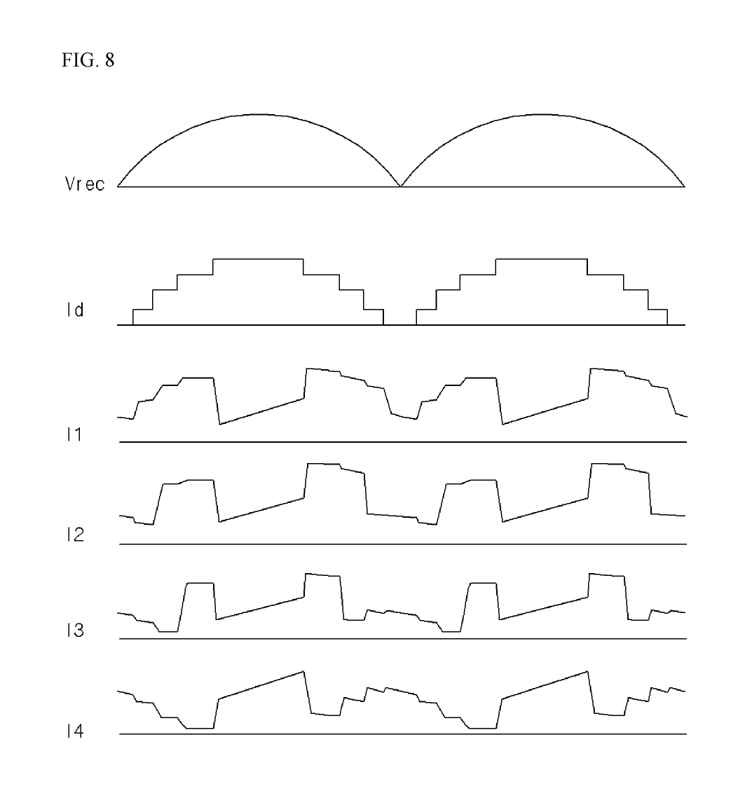

The present invention may be embodied in such a manner that one capacitor C14 is connected in parallel to the LED groups LED1 to LED4 as illustrated in FIG. 7. FIG. 7 illustrates that a capacitor is installed for a plurality of LEDs, unlike the configuration in which the capacitors are connected in parallel to the respective LED groups as illustrated in FIG. 1. FIG. 8 illustrates the waveforms of the driving currents Id and I1 to I4 in the embodiment of FIG. 7.

According to the above-described configuration, the capacitor C14 starts to be charged from the point of time that the rectified voltage Vrec rises over the light emission voltage V4 in the section where the rectified voltage Vrec rises, and the charging is maintained until the rectified voltage Vrec falls to the light emission voltage V4 after rising to the highest value. The capacitor C14 is discharged when the rectified voltage Vrec falls below the light emission voltage V4.

When the rectified voltage Vrec rises from the lowest value to the light emission voltage V4 or falls from the light emission voltage V4 to the lowest value, the driving currents I1 to I3 increase in response to a current provided from the rectifier circuit 12 through current paths which are formed in a stepwise manner through the LED groups LED1 to LED3 and the channel terminals CH1 to CH3. In this case, the changes of the driving currents I1 to I3 follow the change of the driving current Id.

On the other hand, when the rectified voltage Vrec rises from the lowest value to the light emission voltage V4 or falls from the light emission voltage V4 to the lowest value, the driving current I4 decreases while the driving currents I1 to I3 increase, because the discharge of the capacitor C14 is limited by potential rises of the LED groups LED1 to LED3. The decreases of the driving currents I1 to I3 are changed depending on the potentials of the LED groups.

As described above, the LED lighting apparatus according to the present embodiment can provide a discharge current caused by the capacitor C14 when the rectified voltage Vrec falls, and maintain light emission using the discharge current even in a section where the rectified voltage Vrec is low.

In the embodiment of FIG. 7, the amount of discharge current may be decided according to the capacitance of the capacitor C14, and the capacitance of the capacitor C14 may be set to such an extent that the driving current I1 can be retained at a level at which the LED group LED1 can emit light at all times.

Therefore, the LED lighting apparatus according to the embodiment of FIG. 7 can reduce flicker while emitting light as in the embodiment of FIG. 1.

When the capacitor C14 is discharged, the diode D4 blocks a current path which is formed through the sensing resistor Rs, the NMOS transistor of the turned-on switching circuit 34 in the driver 30, and the channel terminal CH4, and induces a reverse current of the discharge current of the capacitor C14. That is, the diode D4 can block the reverse current flow between the channel terminal CH4 of the driver 300 and the capacitor C14, thereby preventing a discharge current leakage.

The diodes D1, D2 and D3 may prevent a discharge current leakage by blocking a current flowing to the LED groups LED1, LED2 and LED3 through the sensing resistor Rs and the driver 300.

The driving module DB according to the present embodiment may be divided into the driving module including no capacitors and the driving module which includes the capacitor or capacitors as illustrated in FIGS. 1, 5 and 7.

When the LED lighting apparatus does not require the flicker reduction function, the LED lighting apparatus may be designed based on the driving module DB with no capacitors, and the driving module DB and the standardized light source module LB may be coupled to satisfy the required specification.

When the LED lighting apparatus requires the flicker reduction function, the LED lighting apparatus may be designed based on the driving module DB with capacitors, and the driving module DB and the standardized light source module LB may be coupled to satisfy the required specification.

In the present embodiments, the light source module LB may be standardized in the same specification, regardless of the flicker reduction function. Therefore, it is possible to reduce the effort, time and cost which are required for developing and manufacturing the LED lighting apparatus according to the embodiment of the present invention.

According to the embodiments of the present invention, the LED lighting apparatus can reduce flicker which occurs in response to changes of the rectified voltage, thereby providing high-quality lighting.

Furthermore, the light source module can be standardized, and then assembled into the other modules for implementing a function required by the LED lighting apparatus, which makes it possible to reduce the effort, time and cost required for developing and manufacturing the LED lighting apparatus for satisfying the required specification.

Furthermore, when the charge voltage of a capacitor is used to provide a discharge current for maintaining light emission of the LED group, the LED lighting apparatus can prevent a discharge current leakage through a feedback path including the channel terminal and the capacitor, thereby removing flicker while providing high-quality lighting.

While various embodiments have been described above, it will be understood to those skilled in the art that the embodiments described are by way of example only. Accordingly, the disclosure described herein should not be limited based on the described embodiments.

1. An LED lighting apparatus comprising:
a lighting module comprising a lighting unit which has LEDs divided into a plurality of LED groups and comprises a rectified voltage input terminal and a plurality of light source module terminals, which are standardized for assembling, wherein the plurality of LED groups sequentially emit light in response to changes of a rectified voltage; and
a driving module comprising: a power supply unit comprising a rectified voltage providing terminal and a plurality of driving module terminals, corresponding to the rectified voltage input terminal and the plurality of light source module terminals, respectively, and configured to output the rectified voltage to the plurality of LED groups through the rectified voltage providing terminal and the rectified voltage input terminal; a driver configured to provide a current path corresponding to light emission of the plurality of LED groups; a capacitor connected in parallel to one or more LED groups among the plurality of LED groups through the plurality of driving module terminals, charged with the rectified voltage, and configured to provide a discharge current for flicker reduction to the one or more LED groups; and a plurality of diodes installed for the respective channel terminals of the driver, and configured to block a reverse current flow in which the discharge current flows through the channel terminals via the driver.

2. The LED lighting apparatus of claim 1, wherein the light emitting module comprises light source module terminals connected to output terminals of the LED groups, and the driving module is electrically connected to the light emitting module through connection between the rectified voltage input terminal and the rectified voltage providing terminal and connections between the plurality of light source module terminals and the plurality of driving module terminals, and a part of the driving module terminals is connected to the channel terminals, wherein the light source module terminals and the driving module terminals are electrically connected to each other while corresponding to each other.

3. The LED lighting apparatus of claim 1, wherein the driving module further comprises a sensing resistor connected to the current path of the driver, and
the sensing resistor provides a sensing voltage for regulating the driving current of the current path.

4. The LED lighting apparatus of claim 3, wherein the driver provides the current path and regulates the driving current of the current path by comparing reference voltages set for the respective LED groups to the sensing voltage of the sensing resistor.

5. The LED lighting apparatus of claim 1, wherein the driver comprises the plurality of capacitors, each of the capacitors is connected in parallel to the respective LED groups.

6. The LED lighting apparatus of claim 1, wherein the plurality of LED groups are divided into a plurality of sets, the driving module comprises the capacitors corresponding to the number of the sets, and the capacitors are connected in parallel to the respective sets.

7. The LED lighting apparatus of claim 1, wherein the capacitor is connected in parallel to the entire diode groups.

8. An LED lighting apparatus comprising:
a light emitting module comprising a plurality of LED groups which are connected in series and sequentially turned on/off in response to changes of a rectified voltage, and having a rectified voltage input terminal for receiving the rectified voltage and a plurality of light source module terminals connected to output terminals of the respective LED groups, wherein the rectified voltage input terminal and the plurality of light source module terminals are standardized for assembling; and
a driving module comprising: a driver having a rectified voltage providing terminal connected to the rectified voltage input terminal so as to provide the rectified voltage, driving module terminals connected one-to-one to the light source module terminals, and channel terminals connected one-to-one to the driving module terminals, and configured to provide a current path corresponding to light emission of one or more of the LED groups through the channel terminals; a capacitor connected between two terminals selected among the rectified voltage providing terminal and the driving module terminals, connected in parallel to one or more of the LED groups, charged with the rectified voltage, and configured to provide a discharge current for flicker reduction to the one or more LED groups; and a plurality of diodes installed for the respective driving module terminals and the respective channel terminals of the driver and configured to block a reverse current flow in which the discharge current flows through the channel terminals via the driver.

9. The LED lighting apparatus of claim 8, wherein the driving module further comprises a power supply unit electrically connected to the light emitting module through connection between the rectified voltage input terminal and the rectified voltage providing terminal and connections between the plurality of light source module terminals and the plurality of driving module terminals, and configured to full-wave rectify an AC voltage of an AC power supply, and output the rectified voltage, and
the rectified voltage is provided to the plurality of LED groups through the rectified voltage providing terminal and the rectified voltage input terminal.

10. The LED lighting apparatus of claim 9, wherein the driving module further comprises a sensing resistor connected to the current path of the driver, and
the sensing resistor provides a sensing voltage for regulating the driving current of the current path.

11. The LED lighting apparatus of claim 10, wherein the driver provides the current path and regulates the driving current by comparing reference voltages set for the respective LED groups to the sensing voltage of the sensing resistor.

12. The LED lighting apparatus of claim 8, wherein the driver comprises the plurality of capacitors, each of the capacitors is installed between the rectified voltage providing terminal and one of the driving module terminals and between the respective driving module terminals so as to be connected in parallel to the respective LED groups.

13. The LED lighting apparatus of claim 8, wherein the plurality of LED groups are divided into a plurality of sets, the driving module comprises the capacitors corresponding to the number of the sets, and each of the capacitors is installed between two terminals selected among the rectified voltage providing terminal and the driving module terminals so as to be connected in parallel to the corresponding set.

14. The LED lighting apparatus of claim 8, wherein the capacitor is installed between the rectified voltage providing terminal and one driving module terminal so as to be connected in parallel to the entire LED diode groups.
